(19) United States
(12) Patent Application Publication
(10) Pub. No.: US 2011/0207334 A1
(43) Pub. Date: Aug. 25, 2011

(54) METHOD OF MANUFACTURING SEMICONDUCTOR DEVICE

(75) Inventors: Yong-soon CHOI, Yongin-si (KR); Hong-gun KIM, Suwon-si (KR); Ha-young YI, Seongnam-si (KR); Gil-heyun CHOI, Seoul (KR); Eun-kee Hong, Seongnam-si (KR)

(73) Assignee: SAMSUNG ELECTRONICS CO., LTD., Suwon-si (KR)

(21) Appl. No.: 12/902,212

(22) Filed: Oct. 12, 2010

(30) Foreign Application Priority Data
Feb. 23, 2010 (KR) 10-2010-0016339

(51) Int. Cl. H01L 21/31

(52) U.S. Cl. 438/762; 257/E21.24

(57) ABSTRACT

A method of manufacturing a semiconductor device includes an improved technique of filling a trench to provide the resulting semiconductor device with better characteristics and higher reliability. The method includes forming a trench in a semiconductor layer, forming a first layer on the semiconductor layer using a silicon source and a nitrogen source to fill the trench, curing the first layer using an oxygen source, and annealing the second layer. The method may also be used to form other types of insulating layers such as an interlayer insulating layer.

### PRIORITY STATEMENT

This application claims the benefit of Korean Patent Application No. 10-2010-0016339, filed on Feb. 23, 2010, in the Korean Intellectual Property Office.

### BACKGROUND

The inventive concept relates to the manufacturing of semiconductor devices. More particularly, the inventive concept relates to a method of manufacturing an insulating layer such as a trench isolation structure, in which a trench in a semiconductor substrate is filled with insulating material, or an interlayer insulating layer.

Smaller design rules of semiconductor devices have led to a need for forming microstructures in semiconductor devices. Such microstructures may include trenches having high aspect ratios which are difficult to fill completely. If, for instance, voids are left in the trenches, the characteristics, reliability, and yield of the resulting semiconductor devices may be reduced. Low yields raise the overall manufacturing costs of the devices.

### SUMMARY

According to an aspect of the inventive concept, there is provided a method of manufacturing a semiconductor device, including: forming a trench in a semiconductor layer; filling the trench using sources of silicon and nitrogen to form a first layer on the semiconductor layer; transforming the first layer into a second layer by curing the first layer using a source of oxygen; and annealing the second layer to transform the second layer into a third layer.

According to another aspect of the inventive concept, there is provided a method of manufacturing a semiconductor device, including: forming a first layer having a first structure on a semiconductor layer, wherein the first structure includes silicon, nitrogen and hydrogen and is a chain of bonded atoms/molecules each consisting of or comprising silicon, nitrogen, or hydrogen; curing the first layer to transform the first layer into a second layer having a second structure, wherein the second structure includes silicon and hydrogen and is a chain of bonded atoms/molecules each consisting of or comprising silicon, hydrogen, nitrogen, or oxygen; and annealing the second layer to transform the second layer into a third layer having a third structure, wherein the third structure is a chain of chemically bonded atoms/molecules including silicon and oxygen atoms chemically bonded to each other.

According to another aspect of the inventive concept, there is provided a method of manufacturing a semiconductor device, the method including: forming a first layer on a semiconductor layer using sources of silicon and nitrogen; transforming the first layer into a second layer by curing the first layer using a source of oxygen; and annealing the second layer to transform the second layer into a third layer.

### BRIEF DESCRIPTION OF THE DRAWINGS

The inventive concept will be more clearly understood from the following detailed description of the preferred embodiments thereof made in conjunction with the accompanying drawings in which:

FIG. 1 is a flowchart illustrating a method of manufacturing a semiconductor device according to the inventive concept;

FIGS. 2A through 2E are cross-sectional views of a substrate and together illustrate an embodiment of a method of manufacturing a semiconductor device according to the inventive concept;

FIG. 3 is another flowchart illustrating a method of manufacturing a semiconductor device according to the inventive concept;

FIG. 4 is still another flowchart illustrating a method of manufacturing a semiconductor device according to the inventive concept; and

FIGS. 5A and 5B are graphs of peaks relative to wave-numbers obtained using Fourier transform infrared spectroscopy (FTIR).

### DETAILED DESCRIPTION OF THE EMBODIMENTS

Preferred embodiments of the inventive concept will now be described with reference to the accompanying drawings. In the drawings, the thicknesses of layers and regions may be exaggerated for clarity. Also, like reference numerals designate like elements throughout the drawings.

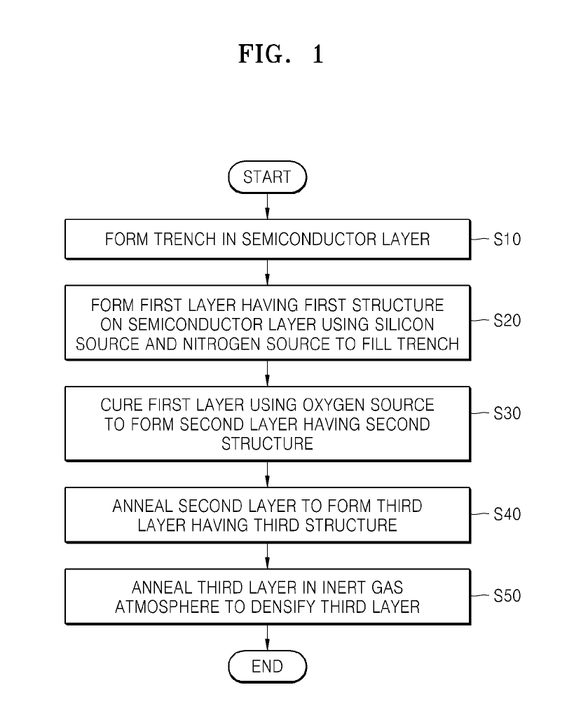

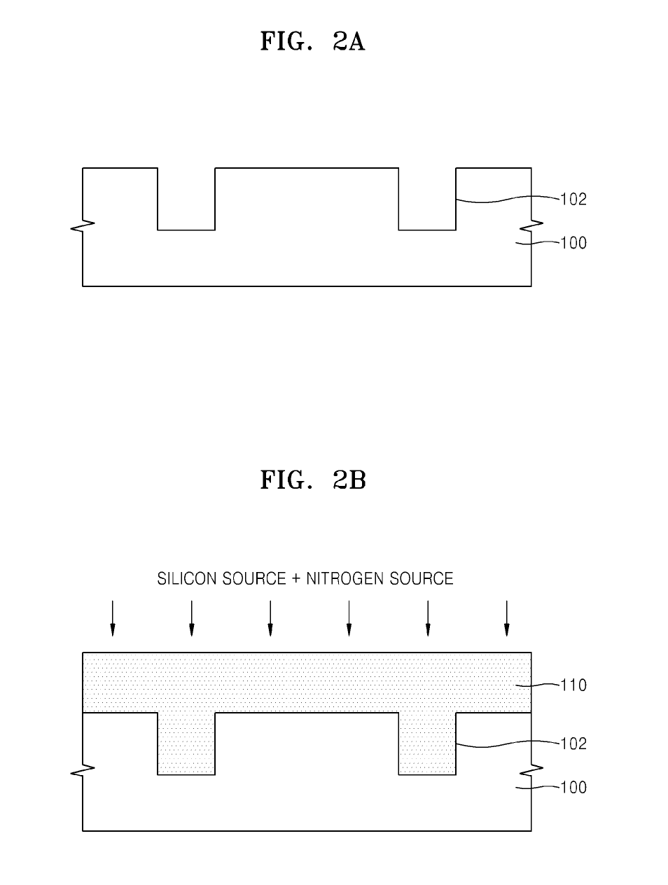

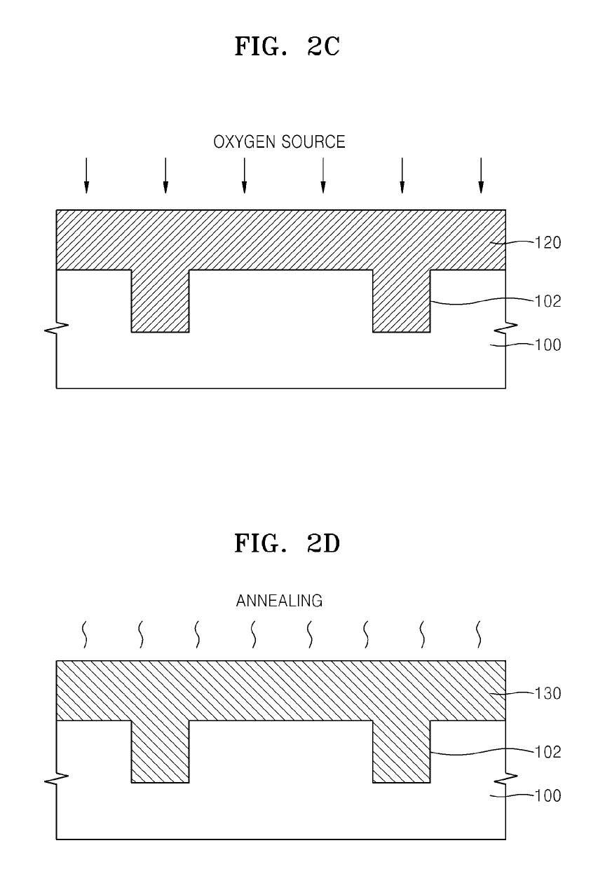

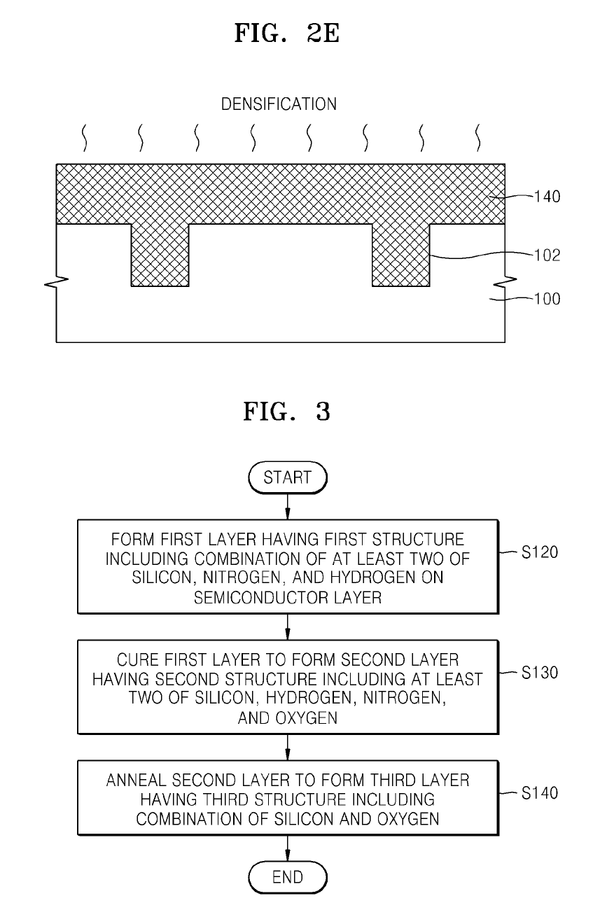

A method of manufacturing a semiconductor device according to the inventive concept will now be described with reference to FIG. 1 and FIGS. 2A through 2E.

Referring first to FIGS. 1 and 2A, a trench 102 is formed in a semiconductor layer 100 (operation S10).

The semiconductor layer 100 is constituted by a semiconductor material, such as silicon (Si) or silicon-germanium (SiGe), an epitaxial layer, a silicon-on-insulator (SOI) layer, or a semiconductor-on-insulator (SEOI) layer. More specifically, the semiconductor layer 100 is an upper part of a substrate that may be formed of one or more of the aforementioned materials. Also, transistors (not shown) may be provided in the semiconductor layer 100. A typical buffer layer (not shown) may also be provided on the semiconductor layer 100.

The trench 102 may be formed using a conventional etching process. For example, the trench 102 may be formed by forming a mask (a photoresist pattern or a hard mask) on the substrate comprising the semiconductor layer 100, then wet or dry etching the layer 100 using the mask as an etch mask. Furthermore, a pad insulating layer (not shown), of an oxide or nitride, may be formed along the surface delimiting the trench 102.

Referring to FIGS. 1 and 2B, a first layer 110 is formed on the semiconductor layer 100 using a silicon source and a nitrogen source to fill the trench 102 (operation S20).

In operation S20, the first layer 110 can be formed using a conventional deposition process. For example, the first layer 110 can be formed using a chemical vapor deposition (CVD) process or an atomic layer deposition (ALD) process, but the inventive concept is not limited thereto. Also, the first layer 110 may be flowable so that the trench 102 may be uniformly and reliably filled with the material of the first layer 110.

In addition to silicon, the silicon source may also include nitrogen and/or hydrogen. Also, the silicon source is preferably carbon-free. The silicon source may be supplied in a liquid phase or otherwise so as to be flowable. For example, the silicon source may be supplied in the form of fine droplets or vapor.

The nitrogen source may include at least one of NH₂*, NH*, and N* and may also include H* (here, * refers to radicals). Also, the nitrogen source may be formed using plasma. The plasma may be formed using a remote plasma method.

The silicon source and the nitrogen source react with each other to form the first layer 110. Preferably, the structure of the first layer 110 includes a chain of at least two (different) atoms/molecules chemically bonded to each other wherein the elements in the chain include silicon and nitrogen and the atoms/molecules consist of one of (in the case of atoms) or comprise at least one of (in the case of molecules) silicon, hydrogen, and nitrogen. For example, the structure (hereinafter referred to as the “first” structure) of the first layer 110 may be a structure represented by the following Formula 1:

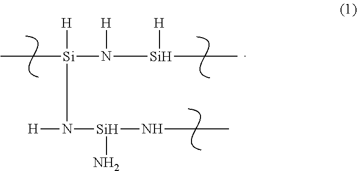

Referring to FIGS. 1 and 2C, the first layer 110 is then cured using an oxygen source to form a second layer 120 (operation S30). The structure of the second layer 120 will be referred to hereinafter as the “second structure”.

The oxygen source contains at least one source of oxygen which may be selected from the group consisting of oxygen (O₂), ozone (O₃), and oxygen radicals (O*). Alternatively, the oxygen source may contain at least one of sulfuric acid (H₂SO₄), hydrogen peroxide (H₂O₂), and an SC1 solution. The SC1 may be a solution of a mixture of NH₄OH, H₂O₂, and H₂O. Alternatively, the oxygen source may be a gaseous mixture including oxygen (O₂) and at least one gas selected from the group consisting of hydrogen (H₂), nitrogen (N₂), and water vapor (H₂O).

The second layer is preferably formed at a temperature of about 100 to 500° C., and more preferably at a temperature of about 100 to 300° C. Also, the second layer may be formed in an atmosphere of inert gas containing helium (He) or neon (Ne). In this case, the oxygen source has a partial pressure preferably in a range of 10 to 50 wt %, and more preferably in a range of 10 to 30 wt %.

The second structure comprises a chain of at least two different atoms/molecules bonded to each other and wherein the elements in the chain are selected from the group consisting of silicon, hydrogen, nitrogen, and oxygen. In the forming of the second structure, oxygen atoms of the oxygen source are substituted for some of the elements of the first structure. For example, the oxygen atoms may substitute for at least some of the nitrogen atoms, some of the molecules of NH₂, or both. The nitrogen and NH₂, which are replaced by the oxygen atoms, may be radicals. For example, the second structure may be a structure represented by the following Formula 2:

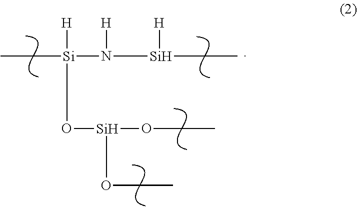

Referring to FIGS. 1 and 2D, the second layer 120 is then annealed to form a third layer 130 (operation S40). The structure of the third layer 130 will be referred to hereinafter as the “third” structure.

The third layer may be formed in an atmosphere of water vapor (H₂O), nitrogen (N₂), oxygen (O₂), or a combination of more than one of such elements/compounds. For example, the third layer may be formed in an H₂O atmosphere at a temperature of about 100 to 500° C., and preferably at a temperature of about 200 to 400° C. Alternatively, the third layer maybe formed in an N₂ atmosphere at a temperature of about 100 to 1000° C., and more preferably at a temperature of about 400 to 900° C. Or the third layer may be formed in an O₂ atmosphere at a temperature of about 100 to 1000° C., and preferably at a temperature of about 200 to 900° C.

The third structure comprises a chain of chemically bonded atoms/molecules each consisting of or comprising silicon or oxygen atoms. That is, oxygen atoms may substitute for the nitrogen atoms and hydrogen atoms of the second structure. As a result, the third structure may be that represented by the following Formula 3:

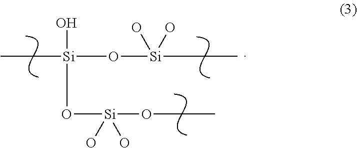

Referring to FIGS. 1 and 2E, the third layer 130 is then annealed in an atmosphere of inert gas and densified (operation S40). The inert gas may be helium (He), neon (Ne), or nitrogen (N₂). In any of these cases, the third layer 130 is preferably densified at a temperature of about 500 to 1000° C., and more preferably at a temperature of about 700 to 900° C. As a result, defects and impurities may be removed from the third layer 130 so that the resulting insulating layer 140 has a denser structure. However, this step (operation S40) is optional. In any case, the resulting insulating layer 140 may be an isolation layer or an interlayer insulating layer.

In the method described above, at least two of operations S20 through S50 may be performed using the same apparatus or different apparatuses. Also, at least two of operations S20 through S50 may be repeated. Furthermore, a planarization process, such as an etch back process or a chemical mechanical polishing (CMP) process, may be subsequently performed if necessary.

FIG. 3 is another flowchart illustrating a method of manufacturing a semiconductor device according to the inventive concept. For brevity, those parts of the method illustrated by FIG. 3 which are similar to the above-described embodiment will not be described in further detail.

Referring to FIG. 3, a first layer is formed on a semiconductor layer (operation S120). Again, the structure of the first layer will be referred to hereinafter as the “first” structure. The first structure includes at least two elements selected from the group consisting of silicon, nitrogen and hydrogen and is a chain of chemically bonded atoms/molecules each consisting of or comprising silicon, nitrogen, or hydrogen. The first structure may be that represented by Formula 1 above.

Subsequently, the first layer may be cured to form a second layer whose structure (second structure) includes at least two elements selected from the group consisting of silicon, hydrogen, nitrogen, and oxygen and is a chain of chemically bonded atoms/molecules each consisting of or comprising silicon, hydrogen, nitrogen, or oxygen (operation S130). In operation S130, at least part of the nitrogen of the first structure is replaced by oxygen. The second structure may be that represented by Formula 2 above.

Subsequently, the second layer is annealed to form a third layer whose structure (third structure) is a chain of chemically bonded atoms/molecules including silicon and oxygen atoms bonded to each other (operation S140). In operation S140, at least some of the nitrogen atoms and hydrogen atoms in the second structure may be replaced by oxygen atoms. The third structure may be that represented by Formula 3 above.

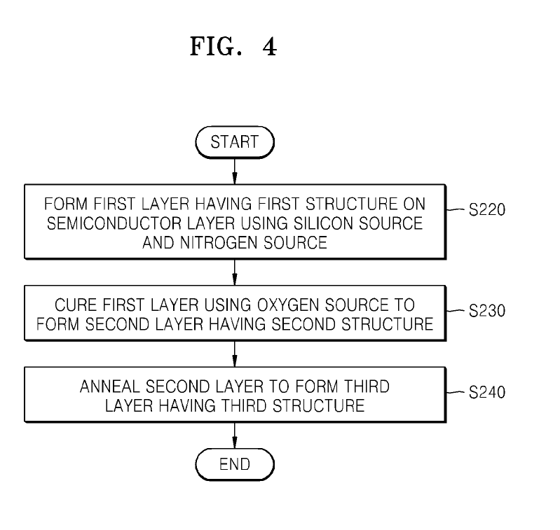

FIG. 4 is still another flowchart illustrating a method of manufacturing a semiconductor device according to the inventive concept. Again, for brevity, those parts of the method illustrated in FIG. 4 which are similar to the above-described embodiment will not be described in further detail.

Referring to FIG. 4, a first layer is formed on a semiconductor layer using a silicon source and a nitrogen source (operation S220). The structure of the first layer (first structure) may be that represented by Formula 1.

Subsequently, the first layer is cured using an oxygen source to form a second layer (operation S230). The structure of the second layer (the second structure) may that represented by Formula 2.

Subsequently, the second layer may be annealed to form a third layer (operation S240). The structure of the third layer (the third structure) may be that represented by Formula 3.

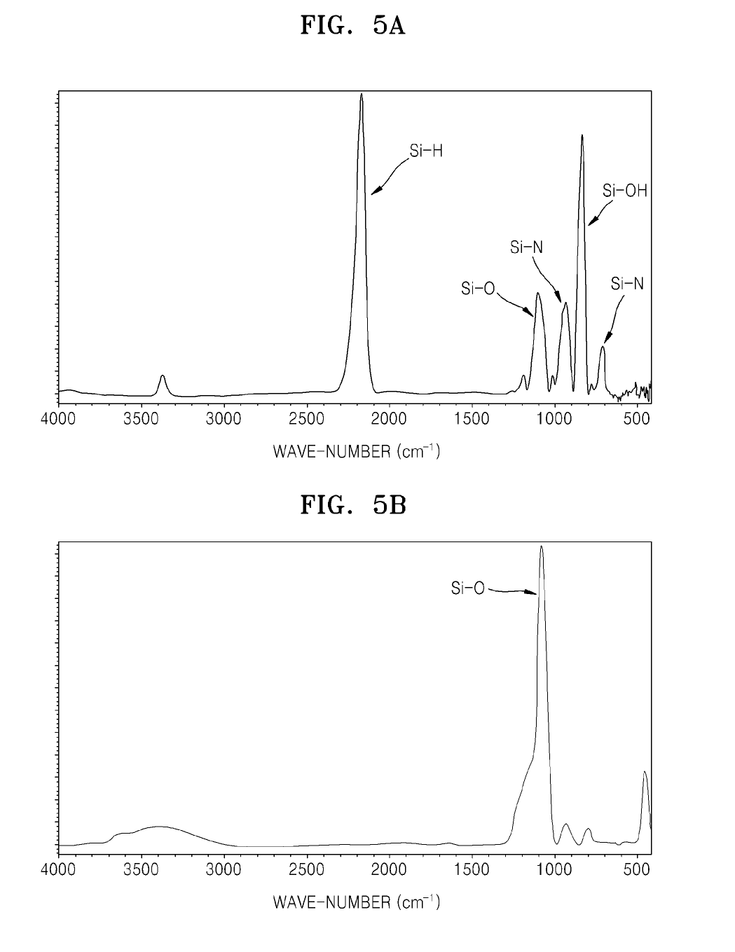

FIGS. 5A and 5B are graphs of peaks relative to wave-numbers obtained using Fourier transform infrared spectroscopy (FTIR).

FIG. 5A shows peaks of the first layer formed according to the embodiment of FIG. 1, and FIG. 5B shows peaks of the third layer formed according to the embodiment of FIG. 1. That is, FIG. 5A shows peaks corresponding to Si—H, Si—N, Si—OH, and Si—O bonds. In other words, the first layer may include Si—H, Si—N, Si—OH, and Si—O bonds. On the other hand, the highest peak in FIG. 5B corresponds to the Si—O bonds, while peaks corresponding to Si—H, Si—N, and Si—OH bonds are not apparent or are slightly visible. In other words, FIG. 5B shows that the third layer has a structure substantially consisting of Si—O bonds.

Finally, embodiments of the inventive concept have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiments described above but by the following claims.

1. A method of manufacturing a semiconductor device, the method comprising:
forming a trench in a semiconductor layer;
filling the trench using sources of silicon and nitrogen to form a first layer on the semiconductor layer;
transforming the first layer into a second layer by curing the first layer using a source of oxygen; and
annealing the second layer to transform the second layer into a third layer,
wherein the third layer comprises a structure represented by the following formula:

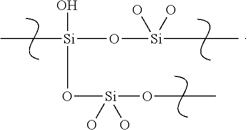

2. The method of claim 1, further comprising densifying the third layer by annealing the third layer in an atmosphere of inert gas.

3. The method of claim 1, wherein the source of silicon consists of silicon and at least one of nitrogen and hydrogen.

4. The method of claim 1, wherein the source of nitrogen comprises at least one of NH₂*, NH*, and N*, wherein * denotes radicals.

5. The method of claim 1, wherein the source of oxygen comprises at least one of oxygen (O₂), ozone (O₃), and oxygen radicals (O*).

6. The method of claim 1, wherein the source of oxygen comprises at least one of sulfuric acid (H₂SO₄), hydrogen peroxide (H₂O₂), and an SC1 solution.

7. The method of claim 1, wherein the source of oxygen is a gaseous mixture comprising oxygen (O₂) and at least one of hydrogen (H₂), nitrogen (N₂), and water vapor (H₂O).

8. The method of claim 1, wherein the first layer comprises a first structure represented by the following formula:

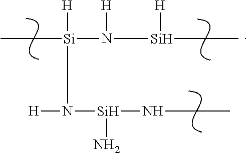

9. The method of claim 1, wherein the second layer comprises a second structure represented by the following formula:

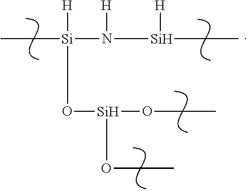

10. (canceled)

11. The method of claim 1, wherein the first layer comprises a first structure containing silicon, nitrogen, and hydrogen.

12. The method of claim 1, wherein the first layer comprises a first structure which includes at least two elements selected from the group consisting of silicon, nitrogen and hydrogen and is a chain of bonded atoms/molecules each comprising silicon, nitrogen, or hydrogen.

13. The method of claim 12, wherein the second layer comprises a second structure which includes at least two elements selected from the group consisting of silicon, hydrogen, nitrogen, and oxygen and is a chain of bonded atoms/molecules each comprising silicon, hydrogen, nitrogen, or oxygen.

14. (canceled)

15. The method of claim 1, wherein the first layer is a layer of flowable material.

16. The method of claim 1, wherein the source of silicon is carbon-free.

17. A method of manufacturing a semiconductor device, the method comprising:
forming a first layer having a first structure on a semiconductor layer, wherein the first structure includes silicon, nitrogen and hydrogen and is a chain of bonded atoms/molecules each comprising silicon, nitrogen, or hydrogen;
curing the first layer to transform the first layer into a second layer having a second structure, wherein the second structure includes silicon and hydrogen and is a chain of bonded atoms/molecules each consisting of or comprising silicon, hydrogen, nitrogen, or oxygen; and
annealing the second layer to transform the second layer into a third layer having a third structure, wherein the third structure is represented by the following formula:

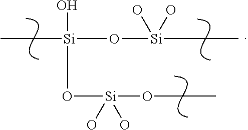

18. The method of claim 17, wherein the forming of the second layer comprises replacing at least part of the nitrogen in the first structure with oxygen.

19. The method of claim 17, wherein the forming of the third layer comprises replacing at least part of the hydrogen in the second structure with oxygen.

20. A method of manufacturing a semiconductor device, the method comprising:
forming a first layer on a semiconductor layer using sources of silicon and nitrogen;
transforming the first layer into a second layer by curing the first layer using a source of oxygen; and
annealing the second layer to transform the second layer into a third layer having a structure represented by the following formula: [chemical structure]
